(19) United States
(12) Patent Application Publication
(10) Pub. No.: US 2017/0323992 A1
(43) Pub. Date: Nov. 9, 2017

(54) SOLAR POWER GENERATOR

(71) Applicants: Esam ELSARRAG, Doha (QA); Yousef AL-HORR, Doha (QA); Gulf Organization for Research and Development, Doha (QA)

(72) Inventors: Esam Elsarrag, Doha (QA); Yousef Al-Horr, Doha (QA); Hans-Fridtjof Pernau, Freiburg (DE)

(73) Assignee: Gulf Organization for Research and Development, Doha (QA)

(21) Appl. No.: 15/527,555

(22) PCT Filed: Nov. 18, 2015
(86) PCT No.: PCT/GB2015/053493

§ 371 Date: May 17, 2017

(30) Foreign Application Priority Data
Nov. 19, 2014 (GB) 1420530.6

(51) Int. Cl. H01L 31/054; H02S 10/30; H02S 10/10; H01M 10/6572; H01M 10/627

(52) U.S. Cl. CPC H01L 31/0549; H01M 10/6572; H01M 10/627; H01L 31/0547; H02S 10/10; H02S 10/30

(57) ABSTRACT

A solar power generator for generating electricity from sunlight in which a photovoltaic panel is provided so as to be oriented for minimising exposure to direct sunlight. A heat absorber is provided, together with a filter for receiving sunlight and filtering ultraviolet and visible light components to the photovoltaic panel and infrared components to the heat absorber. The heat absorber may include a thermoelectric module.

The present invention relates to a solar power generator, and in particular a hybrid solar power generator comprising a photovoltaic panel and a heat absorber.

Photovoltaic panels are used to generate electricity using sunlight.

The efficiency of a conventional photovoltaic panel is around 20% at 20° C., and this performance further decreases as the panel's temperature increases when heated by the sun. Indeed, it has been found that the performance of a photovoltaic panel may decrease by as much as 5% per 10° C. increase in the panel's temperature. This is particularly a problem in countries that have a very hot climate. For example, if a photovoltaic panel is heated up to 100° C., which can occur at peak daytime temperatures in tropical and sub-tropical regions, it has been found that the efficiency of the panel may drop by more than 50%.

In addition, in countries that have a dry or desert climate, the efficiency and performance of a photovoltaic panel may be further reduced by dust covering the surface of the panel.

As a consequence of the above problems, the effectiveness of photovoltaic panels in countries with very hot, dry climates is limited.

The present invention seeks to overcome or mitigate the above problems.

According to an aspect of the present invention, there is provided a solar power generator for generating electricity from sunlight, the solar power generator comprising:

a photovoltaic panel oriented for minimising exposure to direct sunlight;

a heat absorber; and

a filter for receiving sunlight and filtering ultraviolet and visible light components to the photovoltaic panel and infrared components to the heat absorber.

With this arrangement, the photovoltaic panel of the solar power generator is positioned to minimise absorption of direct sunlight. At the same time, a filter within the solar power generator is provided to split the sunlight into its infrared, ultraviolet and visible light components. The filter directs the ultraviolet and visible light components of the sunlight towards the photovoltaic panel, where they are absorbed and used to generate electricity. As such, the orientation of the photovoltaic panel in combination with the filter acts to maximise the proportion of reflected light received by the photovoltaic panel relative to the proportion of direct sunlight received. As such, a greater proportion of the light reaching the active surface of the photovoltaic panel has been filtered by the filter. Consequently, less infrared light is delivered to the photovoltaic panel, which in turn minimises its temperature gain.

The filter simultaneously transmits the infrared component of the sunlight and directs it towards the heat absorber, where it is absorbed as heat, which can be used to, for example, heat water or generate electricity.

With the above arrangement, temperature increase in the photovoltaic panel during its operation is thereby minimised, and as a result the photovoltaic panel maintains its efficiency. This allows the photovoltaic panel to generate more electricity for a longer period of time. Moreover, the provision of a heat absorber provides a hybrid solar power generator that has the combined effect of efficiently generating electricity using a photovoltaic panel together with supplementary heat recovery using the heat absorber.

Preferably, the filter is a reflective filter for reflecting ultraviolet and visible light components of sunlight to the photovoltaic panel. In this way, the reflective filter can be configured to reflect the ultraviolet and visible light components to the surface of the photovoltaic panel.

Preferably, the filter is oriented at substantially 45 degrees with respect to the photovoltaic panel. In this way, delivery of reflected ultraviolet and visible light to the surface of the photovoltaic panel is maximised. Preferably, the filter is configured to focus reflected ultraviolet and visible onto the photovoltaic panel.

Preferably, the photovoltaic panel is oriented substantially vertically. In this way, the photovoltaic panel is arranged in an upright orientation so that its exposure to direct sunlight is minimised. As such, the footprint or surface area of the photovoltaic panel presented to the sky and sun above is minimised. Therefore, the increase in temperature of the panel because of absorption of infrared from direct sunlight is minimised. In addition, the photovoltaic panel being in an upright position minimises the amount of dust and other particulates that can collect on the surface of the photovoltaic panel, because they fall off due to gravity. This prevents decreased efficiency of the photovoltaic panel in a dry or desert climate due to sand or dust covering the surface of the photovoltaic panel and reducing its exposed surface area for absorbing sunlight.

Preferably, the photovoltaic panel has two surfaces for generating electricity, the surfaces facing away from one another, and the solar power generator comprises two heat absorbers, one positioned either side of the photovoltaic panel. As such, the heat absorbers are oriented in a configuration where the position of one heat absorber mirrors the position of the other on opposing sides of the photovoltaic panel. In this way, two active photovoltaic surfaces are provided in a single unit so that more reflected sunlight can be absorbed and therefore the solar power generator can generate more electricity.

Preferably, the photovoltaic panel is a bifacial photovoltaic panel. Conveniently, the solar power generator may comprise two photovoltaic panels, each having a surface for generating electricity.

Preferably, the filter and heat absorber are arranged in an integrated assembly. Conveniently, the filter may be integrally formed with the heat absorber. Alternatively, the filter may be attached to the heat absorber. In this way, minimising the distance between the filter and the heat absorber allows for more efficient transmission of the infrared component of sunlight from the filter to the heat absorber, allowing the heat absorber to be heated to a higher temperature. In addition, the size of the solar power generator is reduced by combining its components.

Preferably, the heat absorber comprises a thermoelectric module. Preferably, the thermoelectric module comprises a thermoelectric generator having a hot side and a cold side, with an absorber plate connected to the hot side. In this way, the infrared component of sunlight that is transmitted through the filter is passed to the thermoelectric module's absorber plate and can be used to generate electricity by heating the absorber plate and creating a temperature differential across the thermoelectric generator. The solar power generator therefore has two separate means of generating electricity that work in combination to provide an overall increased efficiency and performance.

Preferably, the thermoelectric module further comprises a base plate supporting the thermoelectric generator at its cold side, and a frame at the outer periphery of the base plate for attaching the filter. In this way, the thermoelectric generator can be surrounded by and sealed within the base, frame and filter. This protects the thermoelectric generator from dust and rain.

Preferably, empty space within the thermoelectric module is evacuated. Alternatively, empty space within the thermoelectric module is filled with insulating foam. Preferably, there is a gap of less than around 1 mm between the absorber plate and the filter. In this way, heat loss due to convection within the thermoelectric module is mitigated and therefore the temperature of a hot side of the thermoelectric generator is increased. This provides a greater temperature differential across the thermoelectric generator, which increases its efficiency of electricity generation.

Preferably, the base plate of the thermoelectric module is cooled passively. Alternatively, the base plate of the thermoelectric module may be cooled actively by using a thermoelectric cooling arrangement such as piping with a cooling media flowing through it. In this way, cooling of the base plate reduces the temperature of the connected cold side of the thermoelectric generator. This provides a larger temperature differential across the thermoelectric generator, which increases efficiency of electricity generation.

Preferably, the filter is formed from glass.

Preferably, the filter comprises a cold mirror coating. In this way, the coating of the filter very efficiently filters the infrared component of sunlight from the ultraviolet-visible components.

Preferably, the filter is configured to filter wavelengths of sunlight of less than about 800 nm. More preferably, the filter is configured to filter wavelengths of sunlight of between about 200 nm and about 800 nm.

Alternatively, the filter is configured to filter wavelengths of sunlight of less than about 700 nm.

Preferably, the solar power generator further comprises a photovoltaic cooling arrangement connected to the photovoltaic panel. Preferably, when there two photovoltaic panels, the photovoltaic cooling arrangement is provided between the two panels. The cooling arrangement may be cooled passively or actively, for example by using a passive heat sink or an arrangement comprising piping with a cooling media flowing through it. In this way, an additional means is provided to help reduce the temperature of the photovoltaic panel and maintain its peak efficiency so that electricity can be effectively generated. In this connection, with the present invention, since temperature increase within the photovoltaic panel is minimised, the burden placed on the cooling arrangement is also minimised. Accordingly, the energy required to run the cooling arrangement and maintain the photovoltaic panel at an optimal operating temperature is vastly reduced, resulting in decreased operating costs.

Preferably, the photovoltaic panel is laminated in plastic so that it is substantially watertight. In this way, water damage to the photovoltaic panel can be prevented.

Preferably, the photovoltaic panel comprises an outer surface formed from glass. Preferably, the photovoltaic cooling arrangement comprises a cooling media provided in between the glass outer surface and the laminated panel. In this way, the cooling arrangement is positioned very close to the surface of the photovoltaic panel to reduce its temperature more effectively.

Preferably, the solar power generator further comprises a support that acts as a base for mounting the photovoltaic panel and heat absorber. Preferably, the filter may be mounted to the support. In this way the orientation and positions of the photovoltaic panel and heat absorber can be fixed.

According to a further aspect of the present invention, there is provided a solar power generator for generating electricity from sunlight, the solar power generator comprising: a photovoltaic panel; a selective reflector having a surface for reflecting ultraviolet and visible light components of received sunlight towards the photovoltaic panel and transmitting infrared components of received sunlight through its surface; wherein the photovoltaic panel and selective reflector are arranged so that, in use, light received by the photovoltaic panel is primarily composed of reflected light components from the selective reflector.

Preferably, the solar power generator further comprises a thermoelectric module for being heated by the infrared components transmitted through the selective reflector and generating electricity therefrom.

According to a further aspect of the present invention, there is provided a solar power generator array comprising at least two solar power generators according to the above, arranged back to back.

Illustrative embodiments of the invention will now be described, with reference to the accompanying drawings in which:

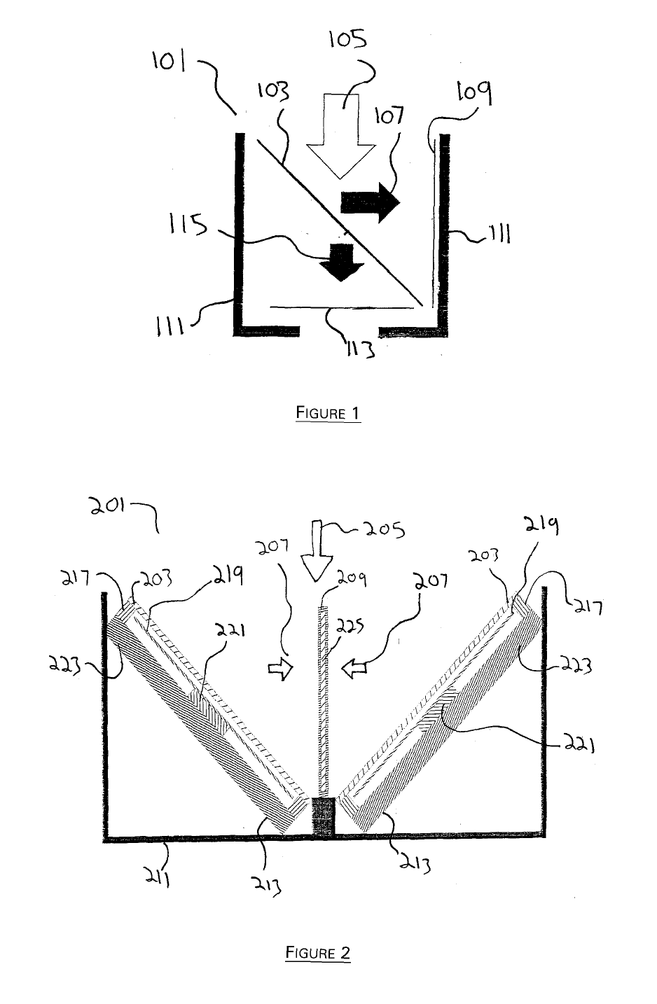

FIG. 1 shows a schematic cross sectional view of a solar power generator according to a first embodiment of the invention; and

FIG. 2 shows a schematic cross sectional view of a solar power generator according to a second embodiment of the invention.

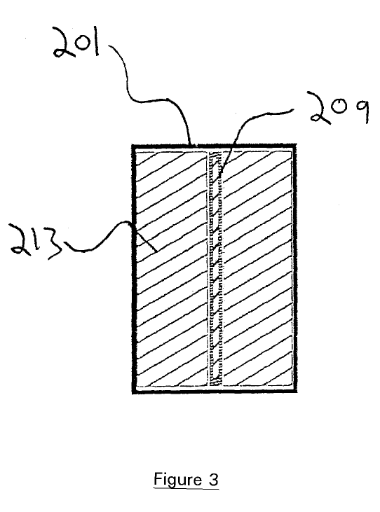

FIG. 3 shows an above plan view of the solar power generator in FIG. 2.

FIG. 1 shows a schematic cross sectional view of a solar power generator 101 according to a first embodiment of the invention. The solar power generator 101 comprises a photovoltaic panel 109 and a thermoelectric module 113 acting as a heat absorber.

In this embodiment, the photovoltaic panel 109 is oriented substantially vertically so that, in this upright position, its exposure to direct sunlight 105 is minimised. That is, its surface area exposed to the sun above is minimised such that the footprint presented to the sun is relatively small. The photovoltaic panel 109 is provided with a photovoltaic cooling arrangement that acts as a heat sink to help reduce the temperature of the photovoltaic panel 109. In this embodiment, the photovoltaic cooling arrangement comprises piping with a liquid cooling medium flowing through it.

The thermoelectric module 113 has a thermoelectric generator and is oriented substantially horizontal so that it is arranged to be perpendicular to the photovoltaic panel 109. The thermoelectric generator of the thermoelectric module 113 has a hot side and a cold side, and is oriented so that its hot side faces towards the sunlight 105. A temperature differential across the thermoelectric generator causes generation of electricity. The cold side of the thermoelectric generator is provided with a thermoelectric cooling arrangement that acts as a heat sink to help reduce its temperature in order increase and optimise the temperature differential across the thermoelectric generator, which optimises generation of electricity. In this embodiment, the thermoelectric cooling arrangement comprises piping with a liquid cooling medium flowing through it.

A reflective filter 103 is disposed between the photovoltaic panel 109 and the thermoelectric module 113. The reflective filter 103 is formed from glass and has a cold mirror coating applied to the glass surface, which permits the transmission of infrared components 115 of the sunlight 105 through it, but acts to reflect ultraviolet and visible light components 107 of the sunlight 105 toward the photovoltaic panel 109. In this embodiment, the filter 103 is oriented at 45 degrees between horizontal and the vertically orientated photovoltaic panel 109. This balances the size of the footprint exposed to the sun above with the amount of light reflected back on to the photovoltaic panel 109. Consequently, the delivery of reflected ultraviolet and visible light 107 to the surface of the photovoltaic panel 109 is maximised.

The solar power generator 101 further comprises a support 111 to which the reflective filter 103, photovoltaic panel 109, and thermoelectric module 113 are mounted.

In use, sunlight 105 is directed to solar power generator 101. The reflective filter 103 effectively splits the sunlight 105 into an infrared component 115 and ultraviolet and visible light components 107. The infrared component 115 is transmitted through the filter 103 to the thermoelectric module 113, where it is absorbed as heat. The ultraviolet and visible light 107 is reflected by the filter 103 to the photovoltaic panel 109.

The photovoltaic panel 109 uses the received ultraviolet and visible light components 107 of the sunlight 105 to generate electricity. However, as the infrared component 115 has been filtered away, it is consequently not absorbed by the photovoltaic panel 109 as heat. Therefore, the photovoltaic panel 109 is able generate electricity using the ultraviolet and visible light components 107 without being heated by the infrared component 115 of the sunlight 105. Accordingly, the photovoltaic panel 109 maintains a lower temperature during use and therefore is able to maintain a higher efficiency.

The photovoltaic cooling arrangement is used to further cool the photovoltaic panel 109, for further maintaining a low temperature and thus a high efficiency. However, by filtering away the infrared component 115 of the sunlight 105 to reduce the heat absorbed by the photovoltaic panel 109, the burden on the photovoltaic cooling arrangement is also reduced. Thus, in the case of an active cooling arrangement, the energy used in active cooling to cool the photovoltaic panel 109 is reduced, resulting in a further increase in overall efficiency.

The infrared component 115 transmitted through the reflective filter 103 is absorbed by the thermoelectric module 113 and thereby heats the hot side of the thermoelectric generator, increasing its temperature relative to the cold side. This creates a temperature differential across the thermoelectric generator, which also causes electricity to be generated. The thermoelectric cooling arrangement is used to further increase the temperature differential across the thermoelectric generator and thus further increase the electricity generated by the thermoelectric generator.

FIG. 2 shows a schematic cross sectional view of a solar power generator 201 according to a second embodiment of the invention. FIG. 3 shows a plan view of the second embodiment. The solar power generator 201 comprises a central photovoltaic panel 209, pair of thermoelectric modules 213 acting as a heat absorber, and a pair of reflective filters 203.

In this second embodiment, the photovoltaic panel 209 is a bifacial photovoltaic panel having two active surfaces for generating electricity from received sunlight. A photovoltaic cooling arrangement 225 is provided in between the two surfaces, to reduce the temperature of both sides of the panel.

Two thermoelectric modules 213 are provided positioned either side of the photovoltaic panel 209. As such, the positioning of one thermoelectric module 213 mirrors that of the other. Each of the thermoelectric modules 213 comprise a thermoelectric generator 221 having a hot side and a cold side. A base plate 223 is attached to the cold side to support the thermoelectric generator 221. The thermoelectric cooling arrangement is provided below the base plate 223. An absorber plate 219 is attached to the hot side of the thermoelectric generator 221 to increase its surface area for absorbing heat. The absorber plate 219 extends symmetrically about the thermoelectric generator 221. The absorber plate 219 and the cooled base plate 223 act to increase the overall temperature differential across the thermoelectric generator 221 and therefore increase the electricity generated.

A frame 217 is provided around the periphery of the base plate 223, and the reflective filter plate 203 is attached to the frame 217. The filter 203, base plate 223 and frame 217 seal in the thermoelectric generator 221 and absorber plate 219 within the thermoelectric module 213. The distance between the surface of the absorber plate 219 and the reflective filter plate 203 is less than 1 mm, and the empty space within the thermoelectric module 213 is evacuated so that minimal air is present. These features help to mitigate convection within each thermoelectric module 213, which would reduce the temperature of the hot side of the thermoelectric generator 221, thereby reducing the overall temperature differential and the electricity generated.

The thermoelectric modules 213 are each inclined to face towards the bifacial photovoltaic panel 209. In this embodiment they are inclined at 45 degrees with respect to the base of the solar power generator 201, i.e. horizontal, in order to maximise the delivery of reflected ultraviolet and visible light 207 from the filters 203 to the surfaces of the photovoltaic panel 209.

The solar power generator 201 further comprises a support 211 to which the photovoltaic panel 209 and thermoelectric modules 213 are mounted to hold them in their respective positions and orientations.

In use, the functionality of the solar power generator 201 is substantially the same as the functionality of the solar power generator 101 in the first embodiment as described above. That is, the ultraviolet and visible light components 207 of sunlight 205 reflects off the reflective filter 203 and is received by the photovoltaic panel 209, which uses it to generate electricity. The infrared component is transmitted through the selective reflective filter 203 and is passed to the thermoelectric module 213, where it heats the hot side of the thermoelectric generator 221, creating a temperature differential across the thermoelectric generator 221, which generates electricity.

In both embodiments, because the photovoltaic panels 109, 209 are oriented substantially vertically, any particulates, such as dust, that contact the surface of the photovoltaic panel 109, 209 do not collect on it and instead fall off due to gravity.

Accordingly, the solar power generators 101 and 201 each provide the combined effect of generating electricity using a photovoltaic panel 109, 209 operating at peak efficiency, and generating electricity using one or more thermoelectric modules 113, 213. As a consequence, since the efficiency of the photovoltaic panels 109, 209 is not substantially decreased by the heating effect of sunlight, the solar power generator 101 and 201 can be used effectively in countries with very hot climates.

It will be understood that the embodiment illustrated above shows applications of the invention only for the purposes of illustration. In practice the invention may be applied to many different configurations, the detailed embodiments being straightforward for those skilled in the art to implement.

For example, whilst the embodiments in FIGS. 1 and 2 show only a single solar power generator 101, 201 multiple solar power generators 101, 201 can be combined to form a solar power generation array.

Furthermore, although in the above illustrative embodiments, the photovoltaic panels have been oriented substantially vertically in order to minimise their exposure to direct sunlight, other configurations are also possible in order to similarly maximise the proportion of reflected light received relative to the proportion of direct sunlight received. For example, a shade may be provided above the photovoltaic panel such that only reflected light reaches its active surface. Equally, the photovoltaic panels may be partially inverted such that its active, electricity generating, surface points relatively downward, thereby functioning as its own shade.

1. A solar power generator for generating electricity from sunlight, the solar power generator comprising:
a photovoltaic panel oriented for minimising exposure to direct sunlight;
a heat absorber; and
a filter for receiving sunlight and filtering ultraviolet and visible light components to the photovoltaic panel and infrared components to the heat absorber.

2. A solar power generator according to claim 1, wherein the heat absorber comprises a thermoelectric module.

3. A solar power generator according to claim 1, wherein the filter is a reflective filter for reflecting ultraviolet and visible light components of sunlight to the photovoltaic panel.

4. A solar power generator according to claim 1, wherein the photovoltaic panel is oriented substantially vertically.

5. A solar power generator according to claim 1, wherein the photovoltaic panel has two surfaces for generating electricity, the surfaces facing away from one another, and the solar power generator comprises two heat absorbers, one positioned either side of the photovoltaic panel.

6. A solar power generator according to claim 5, wherein the photovoltaic panel is a bifacial photovoltaic panel.

7. A solar power generator according to claim 5, wherein the solar power generator comprises two photovoltaic panels, each having one of the surfaces for generating electricity.

8. A solar power generator according to claim 1, wherein the filter and heat absorber are arranged in an integrated assembly.

9. A solar power generator according to claim 2 wherein the thermoelectric module comprises a thermoelectric generator, base plate and a frame at the outer periphery of the base plate, and an absorber plate.

10. A solar power generator according to claim 2, wherein empty space within the thermoelectric module is evacuated.

11. A solar power generator according to claim 1, wherein the filter is formed from glass.

12. A solar power generator according to claim 1, wherein the filter comprises a cold mirror coating.

13. A solar power generator according to claim 1, wherein the filter is configured to filter light having a wavelength of less than about 800 nm,

14. A solar power generator according to claim 1, wherein the filter is oriented at substantially 45 degrees with respect to the solar power generator.

15. A solar power generator for generating electricity from sunlight, the solar power generator comprising:
a photovoltaic panel;
a selective reflector having a surface for reflecting ultraviolet and visible light components of received sunlight towards the photovoltaic panel and transmitting infrared components of received sunlight through its surface;
wherein the photovoltaic, panel and selective reflector are arranged so that, in use, light received by the photovoltaic panel is primarily composed of reflected light components from the selective reflector,

16. A solar power generator according to claim 15, further comprising a thermoelectric module for being heated by the infrared components transmitted through the selective reflector and generating electricity therefrom.

17. A solar power generator array comprising at least two solar power generators according to claim 15 arranged back to back.

18. (canceled)
